(19) United States
(12) Patent Application Publication
(10) Pub. No.: US 2026/0342317 A1
(43) Pub. Date: Oct. 29, 2026

(54) IMPEDANCE CALIBRATION DEVICE

(71) Applicant: QUALITAS SEMICONDUCTOR CO., LTD, Seongnam-si, Gyeonggi-do (KR)

(72) Inventors: Changkyung SEONG, Seoul (KR); Manhyung LEE, Gyeonggi-do (KR)

(73) Assignee: QUALITAS SEMICONDUCTOR CO., LTD, Seongnam-si, Gyeonggi-do (KR)

(21) Appl. No.: 19/117,810

(22) PCT Filed: Sep. 11, 2023
(86) PCT No.: PCT/KR2023/013557

§ 371 Date: Apr. 2, 2025

(30) Foreign Application Priority Data
Oct. 12, 2022 (KR) 10-2022-0130472
Dec. 12, 2022 (KR) 10-2022-0172740

(51) Int. Cl. H03H 11/28; H03K 19/00; H04L 25/02

(52) U.S. Cl. CPC H03H 11/28; H03K 19/0005; H04L 25/0278

(57) ABSTRACT

An impedance calibration device according to one embodiment of the present disclosure includes: a target driver module including a pull-up resistor circuit and a pull-down resistor circuit; a resistance measurement module configured to measure a pull-up resistance value of the pull-up resistor circuit and a pull-down resistance value of the pull-down resistor circuit; and a control module configured to generate a pull-up code for adjusting the pull-up resistance value and a pull-down code for adjusting the pull-down resistance value in order to calibrate the pull-up resistance value and the pull-down resistance value. The control module updates the pull-down code based on the pull-down resistance value and a preset target pull-down resistance value, and updates the pull-up code based on the pull-up resistance value and a preset target pull-up resistance value.

### TECHNICAL FIELD

The technical spirit of the present disclosure relates to an electronic device, and more particularly, to a device and method that measure and calibrate impedance for impedance matching between a transmitter/receiver and a transmission line.

### BACKGROUND ART

The amounts of data that is processed by semiconductor devices widely used in high-performance electronic systems are continuously increasing, and for this purpose, large amounts of data or high-speed signals are transmitted and received via interconnect devices.

In these interconnect devices, there are used transmission lines (channels), transmitters, and receivers having various impedances. However, when each of the output impedance of a transmitter and the input impedance of a receiver does not match the impedance of a transmission line, the reflection of electromagnetic waves may occur at an impedance discontinuity point, which may cause a phenomenon in which transmitted signals are deteriorated. In addition, due to a process voltage temperature (PVT) change or the like, the impedance of each of the components included in an interconnect device may deviate from a normal value set at the time of design, and signal integrity may be affected by impedance mismatching in high-speed communications, resulting in communication errors.

### DISCLOSURE

### Technical Problem

The present disclosure has been conceived in response to the above-described background art, and an object of the present disclosure is to provide a device and method that measure and calibrate the output impedance of a transmitter so that impedance matching with a transmission line is achieved.

An object of the present disclosure is to provide a device capable of effectively calibrating the output impedance of a driver included in a transmitter according to a preset magnitude or condition.

However, the objects to be achieved in the present disclosure are not limited to the objects mentioned above, and other objects not mentioned may be clearly understood based on the following description.

### TECHNICAL SOLUTION

According to one embodiment of the present disclosure for achieving the above-described object, there is disclosed an impedance calibration device including: a target driver module including a pull-up resistor circuit and a pull-down resistor circuit; a resistance measurement module configured to measure a pull-up resistance value of the pull-up resistor circuit and a pull-down resistance value of the pull-down resistor circuit; and a control module configured to generate a pull-up code for adjusting the pull-up resistance value and a pull-down code for adjusting the pull-down resistance value in order to calibrate the pull-up resistance value and the pull-down resistance value. The control module updates the pull-down code based on the pull-down resistance value and a preset target pull-down resistance value, and updates the pull-up code based on the pull-up resistance value and a preset target pull-up resistance value.

Alternatively, the resistance measurement module may include a voltage-controlled oscillator configured such that the output frequency thereof is variable based on an input voltage.

Alternatively, the target driver module may connect one end of the pull-up resistor circuit to a first node based on a first enable signal, and may connect one end of the pull-down resistor circuit to the first node based on a second enable signal. The other end of the pull-up resistor circuit may be supplied with a supply voltage.

Alternatively, the control module may receive a first reference frequency generated from the voltage-controlled oscillator based on a first reference voltage, may receive a first pull-down frequency generated from the voltage-controlled oscillator by using a reference current and a voltage generated based on the pull-down resistor circuit as input, and may generate the pull-down resistance value of the pull-down resistor circuit based on the first reference frequency and the first pull-down frequency.

Alternatively, the control module may update the pull-down code so that the difference between the first reference frequency and the first pull-down frequency becomes less than or equal to a first range.

Alternatively, the control module may receive a second reference frequency generated from the voltage-controlled oscillator by using a second reference voltage, generated at a first ratio based on the supply voltage, as input, may receive a first pull-up frequency generated from the voltage-controlled oscillator based on the voltage of the first node, and may generate the pull-up resistance value of the pull-up resistor circuit based on the second reference frequency and the first pull-up frequency.

Alternatively, the pull-up resistor circuit may include a plurality of transistors connected in parallel, and may selectively connect one or more of the plurality of transistors to a signal transmission path based on the pull-up code.

Alternatively, the pull-down resistor circuit may include a plurality of transistors connected in parallel, and may selectively connect one or more of the plurality of transistors to a signal transmission path based on the pull-down code.

Alternatively, the resistance measurement module may include a counter configured to measure the output frequency, and the counter may generate a first reference count based on the first reference frequency and generate a first pull-down count based on the first pull-down frequency.

According to one embodiment of the present disclosure for achieving the above-described object, there is disclosed an impedance calibration device including: a target driver module including a pull-up resistor circuit capable of adjusting a resistance value based on a pull-up code and a pull-down resistor circuit capable of adjusting a resistance value based on a pull-down code; a resistance measurement module including a reference signal circuit configured to generate a reference signal for measuring a resistance value and a measurement circuit configured to apply the reference signal to the target driver module and measure a generated signal generated at the output node of the target driver module; and a control module configured to control the target driver module or the resistance measurement module and calibrate the measured resistance value. The reference signal circuit may include at least one voltage source, at least one current source, and a plurality of switches configured to selectively connect the voltage source or the current source to the target driver module.

Alternatively, the target driver module may include a first transistor configured to connect one end of the pull-up resistor circuit to a first node based on a first enable signal, and a second transistor configured to connect one end of the pull-down resistor circuit to the first node based on a second enable signal. The other end of the pull-up resistor circuit may be supplied with a supply voltage.

Alternatively, the target driver module may include an output load circuit connected to the first node.

Alternatively, the pull-up resistor circuit may selectively connect one or more of a plurality of transistors to a signal transmission path based on a pull-up code.

Alternatively, the pull-down resistor circuit may selectively connect one or more of a plurality of transistors to a signal transmission path based on a pull-down code.

Alternatively, the resistance measurement module may include a voltage-controlled oscillator configured such that the output frequency thereof is variable based on an input voltage, and a counter configured to measure the output frequency.

Alternatively, the reference signal circuit may include: a first voltage source configured to generate a reference signal when measuring the resistance value of the pull-up resistor circuit; and a second voltage source configured to generate a reference signal when measuring the resistance value of the pull-down resistor circuit, and a current source configured to measure the resistance value of the pull-down resistor circuit.

Alternatively, the reference signal circuit may include: a second node connected to the target driver module; a third node connected to the resistance measurement module; a first switch configured to connect the first voltage source to the third node; a second switch configured to connect the second voltage source to the third node; a fourth switch configured to connect the current source to the second node; and a third switch configured to connect the second node and the third node.

Alternatively, the control module may turn on the second switch and receive a first reference frequency generated from the voltage-controlled oscillator based on the second voltage source, may turn off the second switch, turn on the fourth switch, the third switch, and the second transistor and receive a first pull-down frequency generated from the voltage-controlled oscillator based on the current source and the pull-down resistor circuit, and may generate the pull-down resistance value of the pull-down resistor circuit based on the first reference frequency and the first pull-down frequency.

Alternatively, the control module may update the pull-down code so that the difference between the first reference frequency and the first pull-down frequency becomes less than or equal to a first range.

Alternatively, the control module may turn on the first switch and receive e a second reference frequency generated from the voltage-controlled oscillator based on the first reference voltage source, may turn on the third switch, the first transistor, and the second transistor and receive a first pull-up frequency generated from the voltage-controlled oscillator based on the voltage of the first node, and may generate the pull-up resistance value of the pull-up resistor circuit based on the second reference frequency and the first pull-up frequency. The voltage level of the first reference voltage source may be half the magnitude of the voltage level of a supply voltage.

Alternatively, the control module may update the pull-up code so that the pull-up resistance value becomes a preset pull-up resistance value.

### ADVANTAGEOUS EFFECTS

The present disclosure may correct the output impedance of the transmitter to a desired impedance value even when the output impedance of the transmitter is outside an impedance value range, set at the time of design, due to a PVT change or the like.

The pull-down impedance or pull-up impedance included in the transmitter may be calibrated without being affected by a change in the supply voltage.

### DESCRIPTION OF DRAWINGS

FIG. 1 is a diagram showing a system according to one embodiment of the present disclosure;

FIG. 2 is a block diagram of an impedance calibration device according to one embodiment of the present disclosure;

FIG. 3 is a diagram illustrating an impedance calibration device according to one embodiment of the present disclosure;

FIG. 4 is a flowchart illustrating an impedance calibration method according to one embodiment of the present disclosure;

FIG. 5 is a diagram showing the structure of the driver of a transmitter according to one embodiment of the present disclosure;

FIG. 6 is a diagram illustrating a sub-driver module according to one embodiment of the present disclosure;

FIG. 7 is a diagram illustrating a target driver module according to one embodiment of the present disclosure;

FIG. 8 is a circuit diagram illustrating a pull-up resistor circuit and a pull-down resistor circuit according to one embodiment of the present disclosure;

FIG. 9 is a diagram illustrating changes in the resistance value attributable to changes in the code in a pull-up resistor circuit or a pull-down resistor circuit according to one embodiment of the present disclosure;

FIG. 10 is a diagram illustrating a reference signal circuit included in an impedance calibration device according to one embodiment of the present disclosure; and

FIG. 11 is a diagram illustrating a measurement circuit included in an impedance calibration device according to one embodiment of the present disclosure.

### MODE FOR INVENTION

Embodiments of the present disclosure will be described in detail below with reference to the accompanying drawings so that those having ordinary skill in the art of the present disclosure (hereinafter those skilled in the art) can easily implement the present disclosure. The embodiments presented in the present disclosure are provided to enable those skilled in the art to use or practice the content of the present disclosure. Accordingly, various modifications to embodiments of the present disclosure will be apparent to those skilled in the art. That is, the present disclosure may be implemented in various different forms and is not limited to the following embodiments.

The same or similar reference numerals denote the same or components throughout the specification of the present disclosure. Additionally, in order to clearly describe the present disclosure, reference numerals for parts that are not related to the description of the present disclosure may be omitted in the drawings.

The term “or” used herein is intended not to mean an exclusive “or” but to mean an inclusive “or.” That is, unless otherwise specified herein or the meaning is not clear from the context, the clause “X uses A or B” should be understood to mean one the natural inclusive substitutions. For example, unless otherwise specified herein or the meaning is not clear from the context, the clause “X uses A or B” may be interpreted as any one of a case where X uses A, a case where X uses B, and a case where X uses both A and B.

The term “and/or” used herein should be understood to refer to and include all possible combinations of one or more of listed related concepts.

The terms “include” and/or “including” used herein should be understood to mean that specific features and/or components are present. However, the terms “include” and/or “including” should be understood as not excluding the presence or addition of one or more other features, one or more other components, and/or combinations thereof.

Unless otherwise specified herein or unless the context clearly indicates a singular form, the singular form should generally be construed to include “one or more.”

The term “N-th (N is a natural number)” used herein may be understood as an expression used to distinguish the components of the present disclosure according to a predetermined criterion such as a functional perspective, a structural perspective, or the convenience of description. For example, in the present disclosure, components performing different functional roles may be distinguished a first component or a second component. However, components that are substantially the same within the technical spirit of the present disclosure but should be distinguished for the convenience of description may also be distinguished as a first component or a second component.

The term “impedance” used herein may be a value that impedes the flow of current when voltage is applied to a circuit. In an alternating current (AC) circuit, impedance is an extension of the concept of resistance, and may have magnitude and phase values, unlike resistance, which has only a magnitude value. In a direct current (DC) circuit, impedance and resistance are the same, which may be the case where the phase angle of the impedance is 0. Although impedance calibration is described as a process of performing measurement and calibration based on resistance in the present disclosure, the preset disclosure is not limited thereto.

The foregoing descriptions of the terms are intended to help to understand the present disclosure. Accordingly, it should be noted that unless the above-described terms are explicitly described as limiting the content of the present disclosure, they are not used in the sense of limiting the technical spirit of the present disclosure.

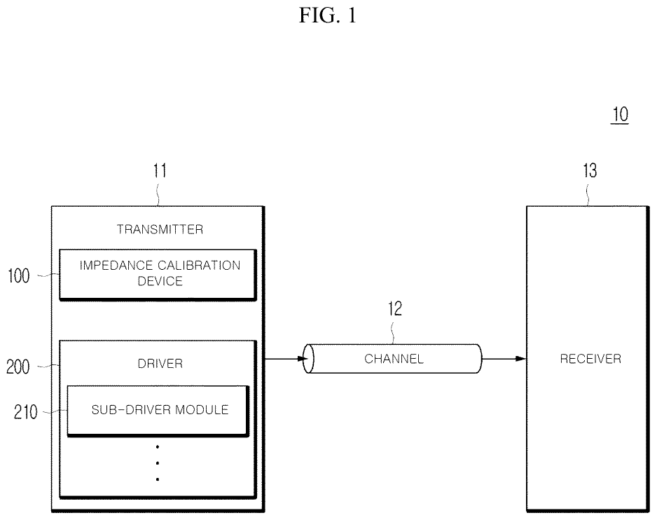

FIG. 1 is a diagram showing a system according to one embodiment of the present disclosure.

Referring to FIG. 1, a system 10 may include a transmitter 11 and a receiver 13 that communicate with each other over a channel 12. The system 10 may include a data transmission/reception circuit, a serializer/deserializer (SERDES) circuit, and a high-speed data transmission system. The transmitter 11 may transmit data or signals to the receiver 13 over the channel 12. The transmitter 11 may include a driver 200, and an impedance calibration device 100 configured to calibrate the output impedance of the driver 200.

The driver 200 may have a series source termination (SST) structure, and may have a structure in which one or more sub-driver modules (or unit driver segments) 210 are connected in parallel. The output impedance of the driver 200 may have a structure in which the output impedances of the respective sub-driver modules 210 are connected in parallel. Although the present invention describes a method of measuring and calibrating output impedance in an SST driver structure as an example, it is not limited thereto, but may be applied to various types of driver structures such as a current mode logic driver (CML) structure.

The impedance calibration device 100 may include components configured to calibrate the output impedance of the driver 200. More specifically, the impedance calibration device 100 may measure the output impedance of a target driver module (or a unit driver replica) replicating the sub-driver modules 210 in order to indirectly measure the output impedance of the driver 200. The target driver module may include the same components included in the sub-driver modules 210 and related to the output impedance, and may further include components configured to measure and calibrate the output impedance. The impedance calibration device 100 may measure the output impedance of the target driver module, and may generate a code for setting the output impedance while performing calibration with a preset output impedance value. The impedance calibration device 100 may calibrate the output impedances of the sub-driver modules 210 included in the driver 200 to a preset output impedance value by transmitting the generated code to the driver 200. The code for calibration is generated based on the pull-up resistor circuit or pull-down resistor circuit of the target driver module, and may be applied to the target driver module or the sub-driver modules 210. The calibration device 100 may control the output impedance of the driver 200 within a desired range by using the generated code.

The channel 12 may be a path or transmission line that physically or electrically connects the transmitter 11 and the receiver 13 to each other. For example, the channel 12 may be implemented using a trace of a printed circuit board (PCB) or a coaxial cable.

The receiver 13 may receive a signal transmitted from the transmitter 11 over the channel 12. The receiver 13 may further include an amplifier or equalizer to restore transmitted signal or compensate for channel loss.

According to the system 10 of the present invention, even when the output impedance of the driver 200 included in the transmitter 11 and the impedance of the channel 12 deviate from a normal range, set at the time of design, due to a PVT change or the like, an impedance matching state may be effectively maintained by adjusting the output impedance of the driver 200 via the calibration device 100.

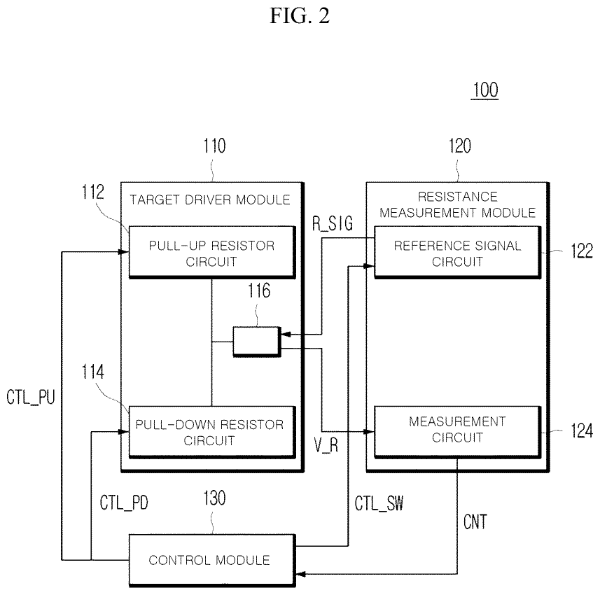

FIG. 2 is a block diagram of an impedance calibration device according to one embodiment of the present disclosure.

Referring to FIG. 2, an impedance calibration device 100 may include a target driver module 110, a resistance measurement module 120, and a control module 130.

The target driver module 110 may be a replica module of any one of the sub-driver modules included in the driver (e.g., 200 of FIG. 1) of the transmitter (e.g., 11 of FIG. 1). The target driver module 110 may include a pull-up resistor circuit 112 and a pull-down resistor circuit 114. The target driver module 110 may have some differences in configuration from the sub-driver module (e.g., 210 of FIG. 1) of the transmitter in order to measure and calibrate the resistances of the pull-up resistor circuit 112 and the pull-down resistor circuit 114. For example, the sub-driver module generates an output signal based on an input signal, whereas the target driver module 110 may control the connection state of the pull-up resistor circuit 112 or the pull-down resistor circuit 114 based on a pull-up enable signal (e.g., a first enable signal) or a pull-down enable signal (e.g., a second enable signal) instead of an input signal. The target driver module 110 may include an output load circuit 116. The output load circuit 116 may include a passive resistance element.

The resistance measurement module 120 may measure the resistance values of the pull-up resistor circuit 112 and the pull-down resistor circuit 114 by applying a reference signal R_SIG to the target driver module 110 and measuring the output signal V_R of the target driver module 110 in response thereto. The reference signal R_SIG may include signals generated from various voltage sources current sources applied to the target driver module 110 by taking into consideration the supply voltage, the target resistance values (the impedance values) of the pull-up resistor circuit 112 and the pull-down resistor circuit 114, etc. For example, a target resistance value including a preset target pull-down resistance value or a preset target pull-up resistance value may be a value set for matching between the output impedance of the driver included in the transmitter and the impedance of the channel.

More specifically, the resistance measurement module 120 may include a reference signal circuit 122 and a measurement circuit 124. The reference signal circuit 122 may sequentially apply preset reference signals R_SIG to the pull-up resistor circuit 112 and pull-down resistor circuit 114 of the target driver module 110. The measurement circuit 124 may calculate the output impedance of the target driver module 110 or the resistance values of the pull-up resistor circuit 112 and the pull-down resistor circuit 114 by measuring the output signal V_R of the target driver module 110.

The control module 130 may control whether the pull-up resistor circuit 112 or the pull-down resistor circuit 114 is connected to the output load circuit 116 by transmitting a pull-up enable signal or a pull-down enable signal to the target driver module 110. The control module 130 may generate a pull-up code for adjusting the resistance value of the pull-up resistor circuit 112, and may generate a pull-down code for adjusting the resistance value of the pull-down resistor circuit 114. The control module 130 may adjust the resistance value of the pull-up resistor circuit 112 by transmitting the pull-up code to the pull-up resistor circuit 112, and may adjust the resistance value of the pull-down resistor circuit 114 by transmitting the pull-down code to the pull-down resistor circuit 114. For example, a pull-up control signal CTL_PU transmitted from the control module 130 to the pull-up resistor circuit 112 may include the pull-up enable signal and the pull-up code. A pull-down control signal CTL_PD transmitted from the control module 130 to the pull-down resistor circuit 114 may include the pull-down enable signal and the pull-down code.

The control module 130 may control a plurality of switching elements included in the reference signal circuit 122 by transmitting a switch control signal CTL_SW to the reference signal circuit 122, and may provide a preset reference signal to the target driver module 110. The control module 130 may receive a signal output from the measurement circuit 124 and calculate the resistance values of the pull-up resistor circuit 112 and the pull-down resistor circuit 114, which are measurement targets. For example, the control module 130 may receive a frequency corresponding to the voltage level of the output node of the target driver module 110 and calculate the resistance value of the measurement target based on the frequency.

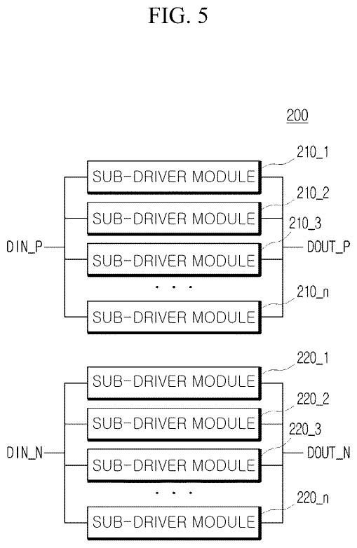

For example, the control module 130 may be at least one processor included in a semiconductor package. The at least one processor may execute a series of instructions or process signals based on a supply voltage. Each of the components included in the impedance calibration device 100 will be described in detail in conjunction with FIGS. 5 to 10.

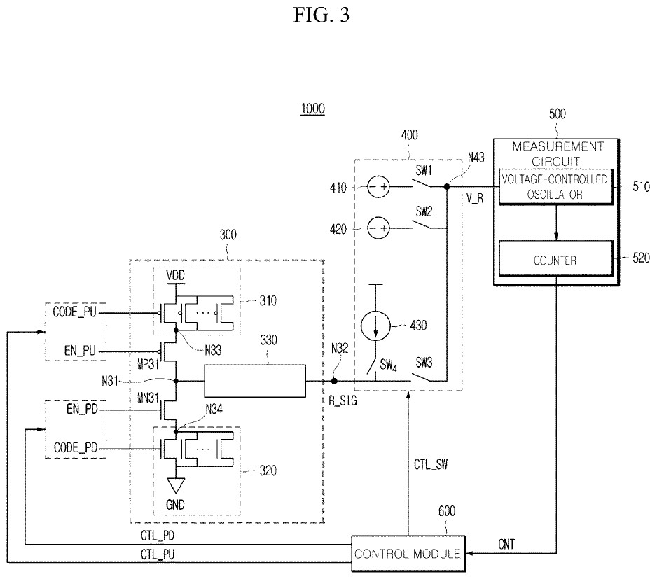

FIG. 3 is a diagram illustrating an impedance calibration device according to one embodiment of the present disclosure.

Referring to FIG. 3, an impedance calibration device 1000 may include a target driver module 300, a reference signal circuit 400, a measurement circuit 500, and a control module 600.

The target driver module 300 may include a pull-up resistor circuit 310, a pull-up enable transistor MP31, a pull-down resistor circuit 320, a pull-down enable transistor MN31, and an output load circuit 330.

One end of the pull-up resistor circuit 310 may be connected to a supply voltage VDD, and the other end thereof may be connected to a third node N33. One end of the pull-down resistor circuit 320 may be connected to a ground node GND, and the other end thereof may be connected to a fourth node N34. One end of the pull-up enable transistor MP31 may be connected to the third node N33, and the other end thereof may be connected to a first node N31. One end of the pull-down enable transistor MN31 may be connected to the fourth node N34, and the other end thereof may be connected to the first node N31. The output load circuit 330 may be connected between the first node N31 and a second node N32, which is an output node.

For example, a pull-up control signal CTL_PU transmitted from the control module 600 to the pull-up resistor circuit 310 may include a pull-up enable signal CODE_PU and a pull-up code. A pull-down control signal CTL_PD transmitted from the control module 600 to the pull-down resistor circuit 320 may include a pull-down enable signal and a pull-down code CODE_PD.

The control module 600 may control whether the pull-up resistor circuit 310 or the pull-down resistor circuit 320 is connected to the first node N31 by transmitting a pull-up enable signal EN_PU or a pull-down enable signal EN_PD to the target driver module 300. The control module 600 may generate a pull-up code CODE_PU for adjusting the resistance value of the pull-up resistor circuit 310, and may generate a pull-down code CODE_PD for adjusting the resistance value of the pull-down resistor circuit 320. The control module 600 may adjust the resistance value of the pull-up resistor circuit 310 by transmitting the pull-up code CODE_PU to the pull-up resistor circuit 310, and may adjust the resistance value of the pull-down resistor circuit 320 by transmitting the pull-down code CODE_PD to the pull-down resistor circuit 320.

The control module 600 may selectively connect one or more of a plurality of PMOS transistors, connected in parallel, between the supply voltage VDD and the third node N33 by transmitting the pull-up code CODE_PU to the pull-up resistor circuit 310. The control module 600 may invert the signal level of the pull-up code CODE_PU and transmit it to the pull-up resistor circuit 310.

The control module 600 may connect the pull-up resistor circuit 310 to the first node N31 by applying the pull-up enable signal EN_PU to the pull-up enable transistor MP31.

The control module 600 may selectively connect one or more of the plurality of NMOS transistors, connected in parallel, between the ground node GND and the fourth node N34 by transmitting the pull-down code CODE_PD to the pull-down resistor circuit 320. The control module 600 may connect the pull-down resistor circuit 320 to the first node N31 by applying the pull-down enable signal EN_PD to the pull-down enable transistor MN31.

The reference signal circuit 400 may include a first voltage source 410, a second voltage source 420, a current source 430, a first switch SW1, a second switch SW2, a third switch SW3, and a fourth switch SW4.

The first voltage source 410 may be a voltage generated based on a supply voltage VDD or driving voltage applied to the transmitter or impedance calibration device 1000. For example, the voltage level of the first voltage source 410 may be half the voltage level of the supply voltage VDD. Depending on the preset resistance value of the pull-down resistor circuit 320, the preset resistance value of the pull-up resistor circuit 310, or other design conditions for impedance matching, the magnitude ratio between the supply voltage and the first voltage source 410 may be set in various manners.

The second voltage source 420 may provide a reference voltage having a preset voltage level. For example, the voltage level of the second voltage source 420 may be a voltage level corresponding to the magnitude of the preset resistance value of the pull-down resistor circuit 320 for impedance matching. The voltage level of the second voltage source 420 may be set by taking into consideration the pull-up resistor circuit 310, the pull-down resistor circuit 320, and the output load circuit 330 included in the target driver module to measure the magnitude of the resistance value of the pull-down resistor circuit 320.

The current source 430 may provide a reference current having a preset magnitude. For example, the reference signal circuit 400 may apply the reference current, generated from the current source 430, to the pull-down resistor circuit 320, and may perform control the voltage of the output node N32 to be generated by the resistance component of the pull-down resistor circuit 320.

The control module 600 may control the first switch SW1, the second switch SW2, the third switch SW3, and the fourth switch SW4 by transmitting a switch control signal CTL_SW to the reference signal circuit 400. For example, the control module 600 may control the first voltage source 410 and the third node N43 to be connected by using the first switch SW1. The control module 600 may control the second voltage source 420 and the third node N43 to be connected by using the second switch SW2. The control module 600 may control the current source 430 and the second node N42 to be connected by using the fourth switch SW4. The control module 600 may control the second node N42 and the third node N43 to be connected by using the third switch SW3. For example, the first switch SW1, the second switch SW2, the third switch SW3, and the fourth switch SW4 may be composed of transistors.

The measurement circuit 500 may include a voltage-controlled oscillator 510 and a counter 520. The measurement circuit 500 may generate an output frequency corresponding to the resistance value of the pull-up resistor circuit 310 or the pull-down resistor circuit 320, which is a measurement target, based on the target voltage V_R output from the target driver module 300.

The voltage-controlled oscillator 510 may generate an oscillation signal based on the target voltage V_R, and the counter 520 may count the oscillation signal during a reference section and provide a counting signal CNT to the control module 600.

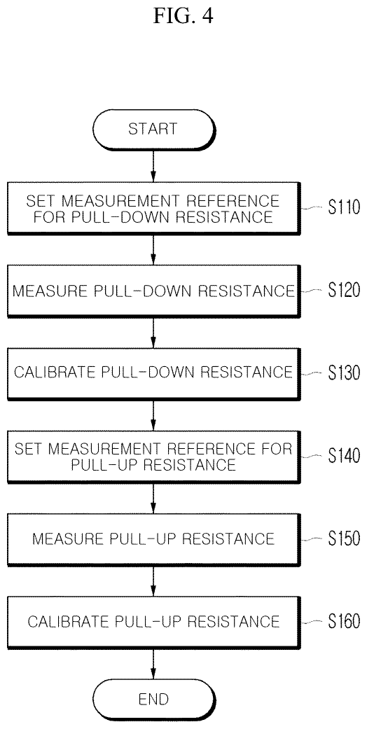

FIG. 4 is a flowchart illustrating an impedance calibration method according to one embodiment of the present disclosure.

Referring to FIGS. 3 and 4, the impedance calibration device 1000 (or the control module 600) may set a measurement reference for the pull-down resistor circuit 320 included in the target driver module 300 in step S110. For example, the impedance calibration device 1000 may turn on the second switch SW2 to generate a first reference count (or a first reference frequency), serving as a measurement reference for the resistance value of the pull-down resistor circuit 320, based on the second voltage source 420 (or a first reference voltage). The voltage-controlled oscillator 510 may generate an oscillation signal based on the second voltage source 420, and the counter 520 may generate a first reference count from the oscillation signal. The voltage level of the second voltage source 420 may be a voltage level corresponding to the magnitude of the target resistance value of the pull-down resistor circuit 320.

The impedance calibration device 1000 may measure the resistance value of the pull-down resistor circuit 320 in step S120. For example, the impedance calibration device 1000 may turn on the pull-down enable transistor MN31 by applying a high-level pull-down enable signal EN_PD and connect the pull-down resistor circuit 320 to the first node N31 to measure the resistance value of the pull-down resistor circuit 320. The impedance calibration device 1000 may turn on the third switch SW3 and the fourth switch SW4 to measure the voltage level generated by applying the current source 430 to the pull-down resistor circuit 320. The voltage-controlled oscillator 510 may generate an oscillation signal based on the voltage level of the second node N32 of the target driver module 300, and the counter 520 may generate a first pull-down count (or a first pull-down frequency) from the oscillation signal. The impedance calibration device 1000 may determine the resistance value of the pull-down resistor circuit 320 based on the first pull-down count.

The impedance calibration device 1000 may calibrate the pull-down resistance value based on the measured resistance value of the pull-down resistor circuit 320 in step S130. For example, the impedance calibration device 1000 may update the pull-down code CODE_PD So that the difference between the first reference count and the first pull-down count becomes less than or equal to a first range in order to adjust the resistance value of the pull-down resistor circuit 320.

For example, the impedance calibration device 1000 may repeat steps S110 to S130 until a pull-down code CODE_PD having the smallest difference between the first reference count and the first pull-down count is found. The impedance calibration device 1000 may select a pull-down code CODE_PD having a low resistance value of the pull-down resistor circuit 320 from among the pull-down codes CODE_PD having the smallest difference between the first reference count and the first pull-down count, or may select a pull-down code CODE_PD having a high resistance value of the pull-down resistor circuit 320 from among the pull-down codes CODE_PD having the smallest difference between the first reference count and the first pull-down count. For example, the impedance calibration device 1000 may select a pull-down code CODE_PD corresponding to the target resistance value in such a manner as to interpolate two values measured in adjacent pull-down codes CODE_PD out of the count (CNT) values measured while changing the pull-down code CODE_PD at a specific ratio and compare the value, obtained by the interpolation, with the first reference count.

The impedance calibration device 1000 may set a measurement reference for the resistance value of the pull-up resistor circuit 310 included in the target driver module 300 in step S140. For example, the impedance calibration device 1000 may turn on the first switch SW1 to generate a second reference count (or a second reference frequency), serving as a measurement reference for the resistance value of the pull-up resistor circuit 310, based on the first voltage source 410 (e.g., a second reference voltage). The voltage-controlled oscillator 510 may generate an oscillation signal based on the first voltage source 410, and the counter 520 may generate a second reference count from the oscillation signal. When the ratio between the target resistance values of the pull-down resistor circuit 320 and the pull-up resistor circuit 310 is 1:1, the voltage level of the first voltage source 410 may be half the magnitude of the supply voltage.

The impedance calibration device 1000 may measure the resistance value of the pull-up resistor circuit 310 in step S150. For example, the impedance calibration device 1000 may turn on the pull-up enable transistor MP31 by applying a low-level pull-up enable signal EN_PU and connect the pull-up resistor circuit 310 to the first node N31 in order to measure the resistance value of the pull-up resistor circuit 310. The impedance calibration device 1000 may turn on the pull-down enable transistor MN31 by applying a high-level pull-down enable signal EN_PD and connect the pull-down resistor circuit 320 to the first node N31 in order to measure the resistance value of the pull-up resistor circuit 310.

The impedance calibration device 1000 may turn on the third switch SW3 to measure the voltage level of the first node N31 in the state in which both the pull-up resistor circuit 310 and the pull-down resistor circuit 320 are connected to the first node N31.

The voltage-controlled oscillator 510 may generate an oscillation signal based on the voltage level of the first node N31 of the target driver module 300, and the counter 520 may generate a first pull-up count (or a first pull-up frequency) from the oscillation signal. The impedance calibration device 1000 may determine the resistance value of the pull-up resistor circuit 320 based on the first pull-up count. Since the voltage level of the first node N31 is determined based on the supply voltage applied to the pull-up resistor circuit 310 and the ratio between the resistance values of the pull-down resistor circuit 320 and the pull-up resistor circuit 310, the resistance value of the pull-up resistor circuit 310 may be estimated by taking into consideration the resistance value of the pull-down resistor circuit 320 determined in step S130. When the ratio between the resistance values of the pull-down resistor circuit 320 and the pull-up resistor circuit 310 is 1:1, the voltage level of the first node N31 may be half the voltage level of the supply voltage.

The impedance calibration device 1000 may calibrate the pull-up resistor based on the measured resistance value of the pull-up resistor circuit 310 in step S160. For example, the impedance calibration device 1000 may update the pull-up code CODE_PU so that the difference between the second reference count and the first pull-up count becomes less than or equal to the first range in order to adjust the resistance value of the pull-up resistor circuit 310.

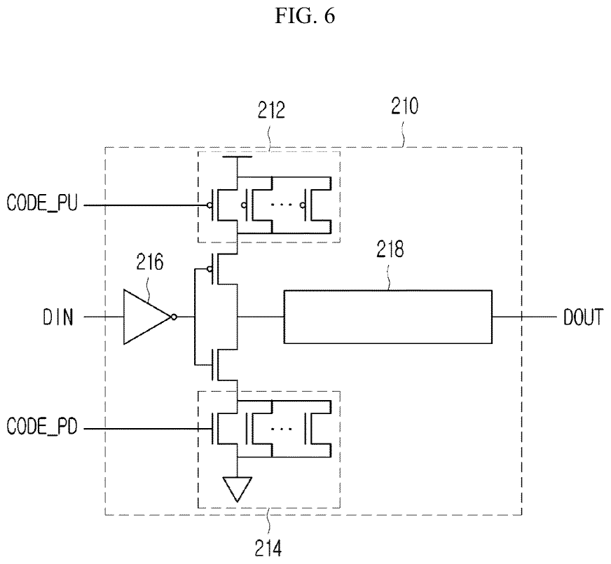

The impedance calibration device 1000 may adjust the output impedance of the driver 200 by transmitting the pull-up code CODE_PU and pull-down code CODE_PD, determined in steps S110 to S160, to the driver 200 or each of the sub-driver modules described in FIGS. 5 and 6.

The impedance calibration device 1000 performs an impedance calibration method so that, even when the output impedance of the transmitter or the driver included in the transmitter is outside the impedance value range set at the time of design due to a PVT change or the like, the output impedance can be corrected to a desired impedance value and also so that the pull-down impedance or pull-up impedance included in the transmitter can be calibrated without being affected by a change in the supply voltage.

FIG. 5 is a diagram showing the structure of the driver of a transmitter according to one embodiment of the present disclosure.

Referring to FIG. 5, a driver 200 may be a voltage-mode driver including a plurality of sub-driver modules. In one embodiment, the driver 200 may include sub-driver modules between a differential input DIN_P or DIN_N and a differential output DOUT_P or DOUT_N. First sub-driver modules 210_1, 210_2, . . . , 210_n may be connected in parallel between a first input DIN_P and a first output DOUT_P. Second sub-driver modules 220_1, 220_2, . . . , 220_n may be connected in parallel between a second input DIN N and a second output DOUT_N. The output impedance may include a first output impedance in which the output impedances of the first sub-driver modules 210_1, 210_2, . . . , 210_n are connected in parallel, and a second output impedance in which the output impedances of the second sub-driver modules 220_1, 220_2, . . . , 220_n are connected in parallel. The structure of the sub-driver module will be illustrated in FIG. 6.

FIG. 6 is a diagram illustrating a sub-driver module according to one embodiment of the present disclosure.

Referring to FIG. 6, the sub-driver module 210 may generate an output signal DOUT based on an input signal DIN. The sub-driver module 210 may include a pull-up resistor circuit 212, a pull-down resistor circuit 214, an inverter 216, and an output load circuit 218. The output load circuit 218 may be a passive resistor. The sub-driver module 210 may connect either the pull-up resistor circuit 212 or the pull-down resistor circuit 214 to the output load circuit 218 according to an input signal DIN.

The pull-up resistor circuit 212 may include a plurality of PMOS transistors that are connected in parallel. The pull-up resistor circuit 212 may selectively connect one or more of the plurality of PMOS transistors to a path in which an output signal DOUT is generated or a signal transmission path according to a pull-up code CODE_PU. In the sub-driver module 210, the pull-up code CODE_PU may be input to the pull-up resistor circuit 212 in a form in which the signal level thereof is inverted.

The pull-down resistor circuit 214 may include a plurality of NMOS transistors that are connected in parallel. The pull-down resistor circuit 214 may selectively connect one or more of the plurality of NMOS transistors to a path in which an output signal DOUT is generated or a signal transmission path according to a pull-down code CODE_D.

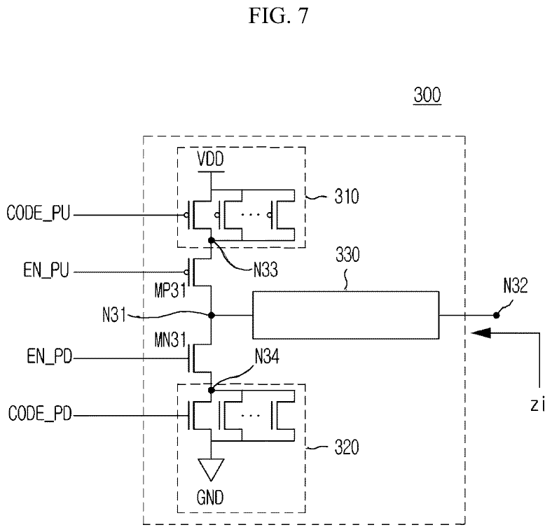

FIG. 7 is a diagram illustrating a target driver module according to one embodiment of the present disclosure.

Referring to FIG. 7, a target driver module 300 may include a pull-up resistor circuit 310, a pull-up enable transistor MP31, a pull-down resistor circuit 320, a pull-down enable transistor MN31, and an output load circuit 330.

One end of the pull-up resistor circuit 310 may be connected to a supply voltage VDD, and the other end thereof may be connected to a third node N33. One end of the pull-down resistor circuit 320 may be connected to a ground node GND, and the other end thereof may be connected to a fourth node N34. One end of the pull-up enable transistor MP31 may be connected to the third node N33, and the other end thereof may be connected to a first node N31. One end of the pull-down enable transistor MN31 may be connected to the fourth node N34, and the other end thereof may be connected to the first node N31. The output load circuit 330 may be connected between the first node N31 and a second node N32, which is an output node.

The pull-up resistor circuit 310 may include a plurality of PMOS transistors that are connected in parallel. The pull-up resistor circuit 310 may selectively connect one or more of the plurality of PMOS transistors between the supply voltage VDD and the third node N33 according to a pull-up code CODE PU. In the target driver module 300, the pull-up code CODE PU may be input to the pull-up resistor circuit 310 in a form in which the signal level thereof is inverted.

The pull-up enable transistor MP31 may connect the pull-up resistor circuit 310 to the first node N31 based on a pull-up enable signal EN_PU.

The pull-down resistor circuit 320 may include a plurality of NMOS transistors that are connected in parallel. The pull-down resistor circuit 320 may selectively connect one or more of the plurality of NMOS transistors between a ground node GND and the fourth node N34 according to a pull-down code CODE_PD. The pull-down enable transistor MN31 may connect the pull-down resistor circuit 320 to the first node N31 based on a pull-down enable signal EN_PD. For example, the impedance calibration device may measure and calibrate the impedance zi of the target driver module 300. The impedance zi of the target driver module 300 may include the resistance value of the pull-up resistor circuit 310 or the resistance value of the pull-down resistor circuit 320.

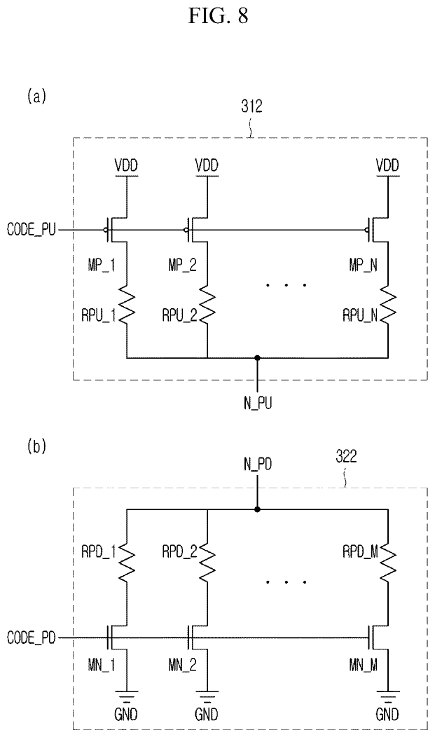

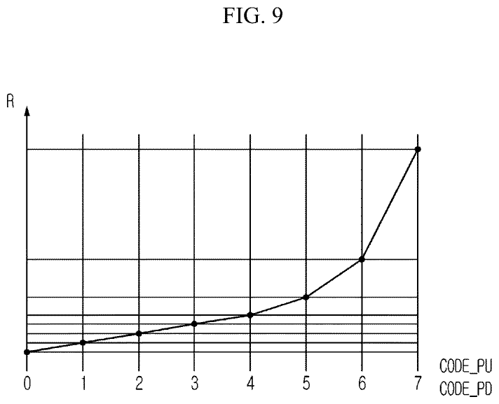

FIG. 8 is a circuit diagram illustrating a pull-up resistor circuit and a pull-down resistor circuit according to one embodiment of the present disclosure, and FIG. 9 is a diagram illustrating changes in the resistance value attributable to changes in the code in a pull-up resistor circuit or a pull-down resistor circuit according to one embodiment of the present disclosure.

Referring to FIG. 8, a target driver module or sub-driver module according to an additional embodiment of the present disclosure may include a pull-up resistor circuit 312 and a pull-down resistor circuit 322. For example, the pull-up resistor circuit 212 described in FIG. 6 or the pull-up resistor circuit 310 described in FIG. 7 may be implemented in the same form as the pull-up resistor circuit 312 of FIG. 8. The pull-down resistor circuit 214 described in FIG. 6 or the pull-down resistor circuit 320 described in FIG. 7 may be implemented in the same form as the pull-down resistor circuit 322 of FIG. 8.

The pull-up resistor circuit 312 may include a plurality of PMOS transistor-resistor sets that are connected between a supply voltage VDD and a connection node N_PU. For example, a first PMOS transistor MP_1 and a first resistor RPU_1 may be connected in series between the supply voltage VDD and the connection node N_PU, a second PMOS transistor MP_2 and a second resistor RPU_2 may be connected in series between the supply voltage VDD and the connection node N_PU, and an N-th PMOS transistor MP_N and an N-th resistor RPU_N may be connected in series between the supply voltage VDD and the connection node N_PU (where N is a natural number equal to or larger than 2).

In one embodiment, the resistance values of the first resistor RPU_1 to the N-th resistor RPU_N may be the same. The first PMOS transistor MP_1 to the N-th PMOS transistor MP_N may be driven by an N-bit pull-up code CODE_PU. In one embodiment, the first resistor RPU_1 to the N-th resistor RPU_N may be resistance components corresponding to the first PMOS transistor MP_1 to the N-th PMOS transistor MP_N, respectively, or may be separate resistance elements.

In one embodiment, the pull-up resistor circuit 312 may be implemented as a binary type driver. The binary type driver may represent a driver configured such that the widths of the plurality of PMOS transistors are sequentially increased by two times. For example, the width of the first PMOS transistor MP_1 may be two times the width of the second PMOS transistor MP_2, and the width of the second PMOS transistor MP_2 may be two times the width of the third PMOS transistor. Since the pull-up resistor circuit 312 is implemented as a binary type driver, the pull-up resistor circuit 312 may provide various resistance values. For example, changes in the resistance value of the pull-up resistor circuit 312 attributable to changes in the pull-up code CODE_PU may be in the form illustrated in the graph of FIG. 9. In the graph of FIG. 9, the X-axis may represent the pull-up code CODE_PU or the pull-down code CODE_PD, and the Y-axis may represent the resistance value R.

In one embodiment, the gate of the first PMOS transistor MP_1 may be driven by the most significant bit value of an N-bit pull-up code CODE_PU, the gate of the second PMOS transistor MP_2 may be driven by the second most significant bit value of the N-bit pull-up code CODE_PU, and the gate of the N-th PMOS transistor MP_N may be driven by the least significant bit value of the N-bit pull-up code CODE_PU. In addition, the pull-up code CODE_PU may be used in various forms and is not limited thereto, and the plurality of PMOS transistor-resistors included in the pull-up resistor circuit 312 may be controlled in various forms.

For example, the connection node N_PU may represent an electrical node to which a circuit element outside the pull-up resistor circuit 312 is connected. For example, the connection node N_PU of the pull-up resistor circuit 312 may be the third node N33 of the pull-up resistor circuit 310, as described in FIG. 5, and may be connected to a pull-up enable transistor MP31.

The pull-down resistor circuit 322 may include a plurality of NMOS transistor-resistor sets that are connected between a ground node GND and a connection node N_PD. For example, a first NMOS transistor MN_1 and a first resistor RPD_1 may be connected in series between the ground node GND and the connection node N_PD, a second NMOS transistor MN_2 and a second resistor RPD_2 may be connected in series between the ground node GND and the connection node N_PD, and an M-th NMOS transistor MN_M and an M-th resistor RPD_M may be connected in series between the ground node GND and the connection node N_PD (where M is a natural number equal to or larger than 2). In one embodiment, the resistance values of the first resistor RPD_1 to the M-th resistor RPD_M may be the same. The first NMOS transistor MN_1 to the M-th NMOS transistor MN_M may be driven by an M-bit pull-down code CODE_PD. In one embodiment, the first resistor RPD_1 to the N-th resistor RPD_N may be resistance components corresponding to the first NMOS transistor MN_1 to the N-th NMOS transistor MN_N, respectively, or may be separate resistance elements.

In one embodiment, the pull-down resistor circuit 322 may be implemented as a binary type driver. The binary type driver may represent a driver configured such that the widths of the plurality of NMOS transistors are sequentially increased by two times. For example, the width of the first NMOS transistor MN_1 may be two times the width of the second NMOS transistor MN_2, and the width of the second NMOS transistor M_2 may be two times the width of the third NMOS transistor. Since the pull-down resistor circuit 322 is implemented as a binary type driver, the pull-down resistor circuit 322 may provide various resistance values. For example, changes in the resistance value of the pull-down resistor circuit 322 attributable to changes in the pull-down code CODE_PD may be in the form illustrated in the graph of FIG. 7.

In one embodiment, the plurality of NMOS transistors included in the pull-down resistor circuit 322 may be driven by the pull-down code CODE_PD in the same manner as described in conjunction with the pull-up resistor circuit 312.

For example, the connection node N_PD may represent an electrical node to which a circuit element outside the pull-down resistor circuit 322 is connected. For example, the connection node N_PD of the pull-down resistor circuit 322 may be the fourth node N34 of the pull-down resistor circuit 322, as described in FIG. 5, and may be connected to the pull-down enable transistor MN31.

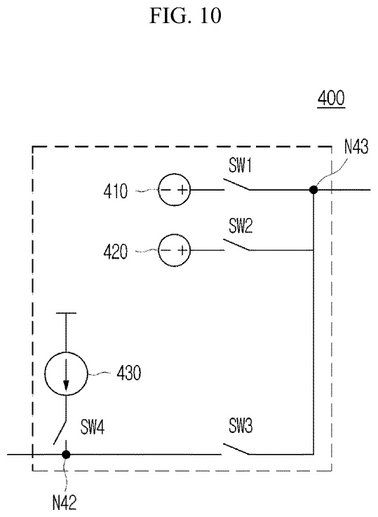

FIG. 10 is a diagram illustrating a reference signal circuit included in an impedance calibration device according to one embodiment of the present disclosure.

Referring to FIG. 10, a reference signal circuit 400 may include a first voltage source 410, a second voltage source 420, a current source 430, a first switch SW1, a second switch SW2, a third switch SW3, and a fourth switch SW4.

The first voltage source 410 may be a voltage generated based on a supply voltage or driving voltage applied to a transmitter or the impedance calibration device. For example, the voltage level of the first voltage source 410 may be half the voltage level of the supply voltage. Depending on the target resistance value of the pull-down resistor circuit, the target resistance value of the pull-up resistor circuit, or other design conditions, the magnitude ratio between the supply voltage and the first voltage source 410 may be set in various manners. For example, the first voltage source 410 may generate a second reference voltage.

The second voltage source 420 may provide a reference voltage having a preset voltage level. For example, the voltage level of the second voltage source 420 may be a voltage level corresponding to the magnitude of the target resistance value of the pull-down resistor circuit. The voltage level of the second voltage source 420 may be set by taking into consideration the pull-up resistor circuit, pull-down resistor circuit, and output load circuit, included in the target driver module, in order to measure the magnitude of the target resistance value of the pull-down resistor circuit. For example, the second voltage source 420 may generate a first reference voltage.

The current source 430 may provide a reference current having a preset magnitude. For example, the reference signal circuit 400 may apply the reference current, generated from the current source 430, to the pull-down resistor circuit, and may control the output node voltage of the target driver module to be generated by the resistance component of the pull-down resistor circuit.

The reference signal circuit 400 may control the first voltage source 410 and the third node N43 to be connected using the first switch SW1. The reference signal circuit 400 may control the second voltage source 420 and the third node N43 to be connected using the second switch SW2. The reference signal circuit 400 may control the current source 430 and the second node N42 to be connected using the fourth switch SW4. The reference signal circuit 400 may control the second node N42 and the third node N43 to be connected using the third switch SW3. For example, the first switch SW1, the second switch SW2, the third switch SW3, and the fourth switch SW4 may be composed of transistors.

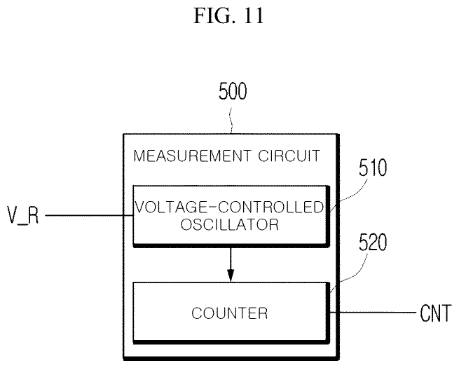

FIG. 11 is a diagram illustrating measurement circuit included in an impedance calibration device according to one embodiment of the present disclosure.

Referring to FIG. 11, a measurement circuit 500 may include a voltage-controlled oscillator 510 and a counter 520. The measurement circuit 500 may generate an output frequency corresponding to the resistance value of a pull-up resistor circuit or a pull-down resistor circuit, which is a measurement target, based on the voltage V_R output from a target driver module.

The voltage controlled oscillator 510 may generate an oscillation signal based on a target voltage V R, and the counter 520 may count the oscillation signal during a reference section and provide a counting signal CNT.

The various embodiments of the present disclosure described above may be combined with one or more additional embodiments, and may be changed within the range understandable to those skilled in the art in light of the above detailed description. The embodiments of the present disclosure should be understood as illustrative but not restrictive in all respects. For example, individual components described as unitary may be implemented in a distributed manner, and similarly, the components described as distributed may also be implemented in a combined form. Accordingly, all changes or modifications derived from the meanings and scopes of the claims of the present disclosure and their equivalents should be construed as being included in the scope of the present disclosure.

1. An impedance calibration device comprising:
a target driver module including a pull-up resistor circuit and a pull-down resistor circuit;
a resistance measurement module configured to measure a pull-up resistance value of the pull-up resistor circuit and a pull-down resistance value of the pull-down resistor circuit; and
a control module configured to generate a pull-up code for adjusting the pull-up resistance value and a pull-down code for adjusting the pull-down resistance value in order to calibrate the pull-up resistance value and the pull-down resistance value;
wherein the control module updates the pull-down code based on the pull-down resistance value and a preset target pull-down resistance value, and updates the pull-up code based on the pull-up resistance value and a preset target pull-up resistance value.

2. The impedance calibration device of claim 1, wherein the resistance measurement module comprises a voltage-controlled oscillator configured such that an output frequency thereof is variable based on an input voltage.

3. The impedance calibration device of claim 2, wherein the target driver module:
connects one end of the pull-up resistor circuit to a first node based on a first enable signal; and
connects one end of the pull-down resistor circuit to the first node based on a second enable signal;
wherein a remaining end of the pull-up resistor circuit is supplied with a supply voltage.

4. The impedance calibration device of claim 3, wherein the control module:
receives a first reference frequency generated from the voltage-controlled oscillator based on a first reference voltage;
receives a first pull-down frequency generated from the voltage-controlled oscillator by using a reference current and a voltage generated based on the pull-down resistor circuit as input; and
generates a pull-down resistance value of the pull-down resistor circuit based on the first reference frequency and the first pull-down frequency.

5. The impedance calibration device of claim 4, wherein the control module updates the pull-down code so that a difference between the first reference frequency and the first pull-down frequency becomes less than or equal to a first range.

6. The impedance calibration device of claim 4, wherein the control module:
receives a second reference frequency generated from the voltage-controlled oscillator by using a second reference voltage, generated at a first ratio based on the supply voltage, as input;
receives a first pull-up frequency generated from the voltage-controlled oscillator based on a voltage of the first node; and
generates a pull-up resistance value of the pull-up resistor circuit based on the second reference frequency and the first pull-up frequency.

7. The impedance calibration device of claim 1, wherein the pull-up resistor circuit comprises a plurality of transistors connected in parallel, and selectively connects one or more of the plurality of transistors to a signal transmission path based on the pull-up code.

8. The impedance calibration device of claim 1, wherein the pull-down resistor circuit comprises a plurality transistors connected in parallel, and selectively connects one or more of the plurality of transistors to a signal transmission path based on the pull-down code.

9. The impedance calibration device of claim 4, wherein:
the resistance measurement module comprises a counter configured to measure the output frequency; and
the counter generates a first reference count based on the first reference frequency and generates a first pull-down count based on the first pull-down frequency.

10. An impedance calibration device comprising:
a target driver module including a pull-up resistor circuit capable of adjusting a resistance value based on a pull-up code and a pull-down resistor circuit capable of adjusting a resistance value based on a pull-down code;
a resistance measurement module including a reference signal circuit configured to generate a reference signal for measuring a resistance value and a measurement circuit configured to apply the reference signal to the target driver module and measure a generated signal generated at an output node of the target driver module; and
a control module configured to control the target driver module or the resistance measurement module and calibrate the measured resistance value;
wherein the reference signal circuit comprises at least one voltage source, at least one current source, and a plurality of switches configured to selectively connect the voltage source or the current source to the target driver module.

11. The impedance calibration device of claim 10, wherein:
the target driver module comprises:
a first transistor configured to connect one end of the pull-up resistor circuit to a first node based on a first enable signal; and
a second transistor configured to connect one end of the pull-down resistor circuit to the first node based on a second enable signal; and
a remaining end of the pull-up resistor circuit is supplied with a supply voltage.

12. The impedance calibration device of claim 11, wherein the target driver module comprises an output load circuit connected to the first node.

13. The impedance calibration device of claim 10, wherein the pull-up resistor circuit selectively connects one or more of a plurality of transistors to a signal transmission path based on a pull-up code.

14. The impedance calibration device of claim 10, wherein the pull-down resistor circuit selectively connects one or more of a plurality of transistors to a signal transmission path based on a pull-down code.

15. The impedance calibration device of claim 11, wherein the resistance measurement module comprises a voltage-controlled oscillator configured such that an output frequency thereof is variable based on an input voltage, and a counter configured to measure the output frequency.

16. The impedance calibration device of claim 15, wherein the reference signal circuit comprises:
a first voltage source configured to generate a reference signal when measuring a resistance value of the pull-up resistor circuit; and
a second voltage source configured to generate a reference signal when measuring a resistance value of the pull-down resistor circuit, and a current source configured to measure the resistance value of the pull-down resistor circuit.

17. The impedance calibration device of claim 16, wherein the reference signal circuit comprises:
a second node connected to the target driver module;
a third node connected to the resistance measurement module;
a first switch configured to connect the first voltage source to the third node;
a second switch configured to connect the second voltage source to the third node;
a fourth switch configured to connect the current source to the second node; and
a third switch configured to connect the second node and the third node.

18. The impedance calibration device of claim 17, wherein the control module:
turns n the second switch, and receives a first reference frequency generated from the voltage-controlled oscillator based on the second voltage source;
turns off the second switch, turns on the fourth switch, the third switch, and the second transistor, and receives a first pull-down frequency generated from the voltage-controlled oscillator based on the current source and the pull-down resistor circuit; and
generates a pull-down resistance value of the pull-down resistor circuit based on the first reference frequency and the first pull-down frequency.

19. The impedance calibration device of claim 18, wherein the control module updates the pull-down code so that a difference between the first reference frequency and the first pull-down frequency becomes less than or equal to a first range.

20. The impedance calibration device of claim 18, wherein:
the control module:
turns n the first switch, and receives a second reference frequency generated from the voltage-controlled oscillator based on the first reference voltage source;
turns on the third switch, the first transistor, and the second transistor, and receives a first pull-up frequency generated from the voltage-controlled oscillator based on a voltage of the first node; and
generates a pull-up resistance value of the pull-up resistor circuit based on the second reference frequency and the first pull-up frequency; and
a voltage level of the first reference voltage source is half a magnitude of a voltage level of a supply voltage.

21. The impedance calibration device of claim 20, wherein the control module updates the pull-up code so that the pull-up resistance value becomes a preset pull-up resistance value.
